(19) United States
(12) Patent Application Publication
(10) Pub. No.: US 2026/0186023 A1
(43) Pub. Date: Jul. 2, 2026

(54) DISPLAY PANEL, DISPLAY-PANEL TESTING SYSTEM, AND DISPLAY-PANEL TESTING METHOD

(71) Applicant: Xiamen Tianma Optoelectronics Co., Ltd., Xiamen (CN)

(72) Inventors: Zishan LI, Xiamen (CN); Zongjun ZOU, Xiamen (CN)

(21) Appl. No.: 19/241,952

(22) Filed: Jun. 18, 2025

(30) Foreign Application Priority Data
Dec. 31, 2024 (CN) 202411997237.1

(51) Int. Cl. G01R 1/067; G01R 31/28

(52) U.S. Cl. CPC G01R 1/06794; G01R 31/2825

(57) ABSTRACT

A display panel, a display-panel testing system, and a display-panel testing method are provided. The display panel includes a display area and a non-display area. The non-display area at least partially surrounds the display area. The display area includes a display driving signal line. The non-display area includes a plurality of pads, and the plurality of pads includes one or more first pad and one or more second pad. One or more first pad of the one or more first pad is a test pad connected to the display driving signal line. One or more second pad of the one or more second pad is not connected to the display driving signal line, and one or more second pad of the one or more second pad is input with a first voltage signal and outputs a feedback signal.

### CROSS-REFERENCE TO RELATED APPLICATION

The present disclosure claims priority of Chinese Patent Application No. 202411997237.1, filed on Dec. 31, 2024, the entire content of which is hereby incorporated by reference.

### FIELD OF THE DISCLOSURE

The present disclosure generally relates to the field of display technology and, more particularly, relates to a display panel, a display-panel testing system, and a display-panel testing method.

### BACKGROUND

With continuous development of science and technology, various display devices are widely used in people's daily life and work. Display devices have brought great convenience to people's daily life and work. A display panel is a main component of a display device, and the design of a display panel directly or indirectly affects display effect of the display device.

During a fabrication procedure of a display panel, a light-up test by a test fixture may be needed before the display panel may be moved to a next fabrication process. When probes on the test fixture are misaligned with pads on the display panel during docking, the display panel may be burned after the test fixture is powered on.

As such, how to determine whether there is misalignment between the probes on the test fixture and the pads on the display panel is a technical problem that needs to be solved urgently by those skilled in the art.

### SUMMARY

One aspect of the present disclosure includes a display panel. The display panel includes a display area and a non-display area. The non-display area at least partially surrounds the display area. The display area includes a display driving signal line. The non-display area includes a plurality of pads, and the plurality of pads includes one or more first pad and one or more second pad. One or more first pad of the one or more first pad is a test pad connected to the display driving signal line. One or more second pad of the one or more second pad is not connected to the display driving signal line, and one or more second pad of the one or more second pad is input with a first voltage signal and outputs a feedback signal.

Another aspect of the present disclosure includes a display-panel testing system. The display-panel testing system includes a display panel and a testing fixture. The display panel includes a display area and a non-display area. The non-display area at least partially surrounds the display area, the display area includes a display driving signal line. The non-display area includes a plurality of pads, the plurality of pads includes one or more first pad and one or more second pad. One or more first pad of the one or more first pad is a test pad connected to the display driving signal line. One or more second pad of the one or more second pad is not connected to the display driving signal line, and one or more second pad of the one or more second pad is input with a first voltage signal and outputs a feedback signal. The test fixture includes one or more first probe and one or more second probe. One or more first probe of the one or more first probe is electrically connected to the one or more the first pad in the display panel, and one or more second probe of the one or more second probe is electrically connected to the one or more second pad in the display panel.

Another aspect of the present disclosure includes a display-panel testing method. The display-panel testing method is applicable to a display-panel testing system. The display-panel testing system includes a display panel and a testing fixture. The display panel includes a display area and a non-display area. The non-display area at least partially surrounds the display area, the display area includes a display driving signal line. The non-display area includes a plurality of pads, the plurality of pads includes one or more first pad and one or more second pad. One or more first pad of the one or more first pad is a test pad connected to the display driving signal line. One or more second pad of the one or more second pad is not connected to the display driving signal line, and one or more second pad of the one or more second pad is input with a first voltage signal and outputs a feedback signal. The test fixture includes one or more first probe and one or more second probe. One or more first probe of the one or more first probe is electrically connected to the one or more the first pad in the display panel, and one or more second probe of the one or more second probe is electrically connected to the one or more second pad in the display panel. The display-panel testing method includes a first test stage. In the first test stage, the display-panel testing method includes: connecting one or more first probe of the one or more first probe on the test fixture to one or more first pad of the one or more first pad, and connecting one or more second probe of the one or more second probe on the test fixture to one or more second pad of the one or more second pad; sending the first voltage signal to the one or more second pad through the one or more second probe, and collecting the feedback signal; and determining whether the one or more second probe and the one or more second pad are misaligned based on the feedback signal.

Other aspects of the present disclosure may be understood by those skilled in the art in light of the description, the claims, and the drawings of the present disclosure.

### BRIEF DESCRIPTION OF THE DRAWINGS

The following drawings are merely examples for illustrative purposes according to various disclosed embodiments and are not intended to limit the scope of the present disclosure.

FIG. 1 illustrates a schematic structural diagram of a display panel consistent with the disclosed embodiments of the present disclosure;

FIG. 2 illustrates a schematic structural diagram of a test fixture consistent with the disclosed embodiments of the present disclosure;

FIG. 3 illustrates a schematic diagram of an alignment relationship between a probe on a test fixture and a pad on a display panel, consistent with the disclosed embodiments of the present disclosure;

FIG. 4 illustrates a schematic diagram of another alignment relationship between a probe on a test fixture and a pad on a display panel, consistent with the disclosed embodiments of the present disclosure;

FIG. 5 illustrates a schematic flow chart of a display-panel testing method consistent with the disclosed embodiments of the present disclosure;

FIG. 6 illustrates a schematic structural diagram of another display panel consistent with the disclosed embodiments of the present disclosure;

FIG. 7 illustrates a schematic diagram of a capacitor structure consistent with the disclosed embodiments of the present disclosure;

FIG. 8 illustrates a schematic structural diagram of an equivalent circuit of a display-panel testing system, consistent with the disclosed embodiments of the present disclosure;

FIG. 9 illustrates a schematic flow chart of another display-panel testing method consistent with the disclosed embodiments of the present disclosure;

FIG. 10 illustrates a schematic curve of voltage and time, consistent with the disclosed embodiments of the present disclosure;

FIG. 11 illustrates another schematic curve of voltage and time, consistent with the disclosed embodiments of the present disclosure;

FIG. 12 illustrates a schematic structural diagram of another display panel consistent with the disclosed embodiments of the present disclosure;

FIG. 13 illustrates a schematic structural diagram of an equivalent circuit of another display-panel testing system, consistent with the disclosed embodiments of the present disclosure;

FIG. 14 illustrates a schematic flow chart of another display-panel testing method consistent with the disclosed embodiments of the present disclosure;

FIG. 15 illustrates a schematic structural diagram of another display panel consistent with the disclosed embodiments of the present disclosure;

FIG. 16 illustrates a schematic structural diagram of an equivalent circuit of another display-panel testing system, consistent with the disclosed embodiments of the present disclosure;

FIG. 17 illustrates a schematic flow chart of another display-panel testing method consistent with the disclosed embodiments of the present disclosure;

FIG. 18 illustrates a schematic structural diagram of another display panel consistent with the disclosed embodiments of the present disclosure;

FIG. 19 illustrates a schematic structural diagram of another display panel consistent with the disclosed embodiments of the present disclosure;

FIG. 20 illustrates a schematic structural diagram of another display panel consistent with the disclosed embodiments of the present disclosure;

FIG. 21 illustrates a schematic structural diagram of another display panel consistent with the disclosed embodiments of the present disclosure;

FIG. 22 illustrates a schematic structural diagram of another display panel consistent with the disclosed embodiments of the present disclosure;

FIG. 23 illustrates a schematic structural diagram of another display panel consistent with the disclosed embodiments of the present disclosure;

FIG. 24 illustrates a schematic structural diagram of another display panel consistent with the disclosed embodiments of the present disclosure;

FIG. 25 illustrates a schematic flow chart of another display-panel testing method consistent with the disclosed embodiments of the present disclosure;

FIG. 26 illustrates a schematic diagram of test stage distribution corresponding to a display-panel testing method, consistent with the disclosed embodiments of the present disclosure;

FIG. 27 illustrates a timing diagram corresponding to a display-panel testing method, consistent with the disclosed embodiments of the present disclosure;

FIG. 28 illustrates a schematic diagram of test stage distribution corresponding to another display-panel testing method, consistent with the disclosed embodiments of the present disclosure; and

FIG. 29 illustrates a timing diagram corresponding to another display-panel testing method, consistent with the disclosed embodiments of the present disclosure.

### DETAILED DESCRIPTION

To make the objectives, technical solutions and advantages of the present disclosure clearer and more explicit, the present disclosure is described in further detail with accompanying drawings and embodiments. It should be understood that the specific exemplary embodiments described herein are only for explaining the present disclosure and are not intended to limit the present disclosure.

Technologies, methods, and equipment known to those of ordinary skill in relevant fields may not be discussed in detail, but where appropriate, these technologies, methods, and equipment should be regarded as part of the present disclosure.

It should be noted that in the present disclosure, when an element (such as a layer, a film, a region, or a substrate) is referred to as being “over” another element, the element may be directly on the other element, or intervening elements may be present. In addition, in the present disclosure, when an element is described as being “connected” to another element, the element may be “directly connected” to the other element, or “connected” to the other element through a third element.

Directional or positional relationships indicated by terms, such as “upper”, “lower”, “top”, “bottom”, “inner”, and “outer”, are based on the directional or positional relationships shown in the drawings. These terms are only for convenience of description, and for simplifying the description. These terms do not indicate or imply that the devices or elements referred to must have a specific orientation, be constructed and operate in a specific orientation. These terms should not be understood as a limit to the present disclosure.

It should be noted that in the present disclosure, relational terms such as “first” and “second” are only used to distinguish one entity or operation from another entity or operation, and do not necessarily require or imply that such actual relationship or sequence exists between these entities or operations. Terms “comprise”, “include” or any other variations thereof are intended to cover a non-exclusive inclusion. A process, method, article, or apparatus that includes a series of elements includes not only the series of elements, but also other elements not expressly listed, or elements inherent to such a process, method, article, or apparatus. Without further limitation, an element defined by a statement like “comprises a . . . ” does not exclude the presence of additional identical elements in a process, method, article, or apparatus that includes the foregoing element. In the present disclosure, that layer A and layer B are “disposed on a same layer” means that layer A and layer B are made of a same material and in a same process.

Reference will now be made in detail to embodiments of the present disclosure, which are illustrated in the accompanying drawings. Similar labels and letters designate similar items in the drawings. Once an item is defined in one drawing, the item may not be defined and discussed in subsequent drawings.

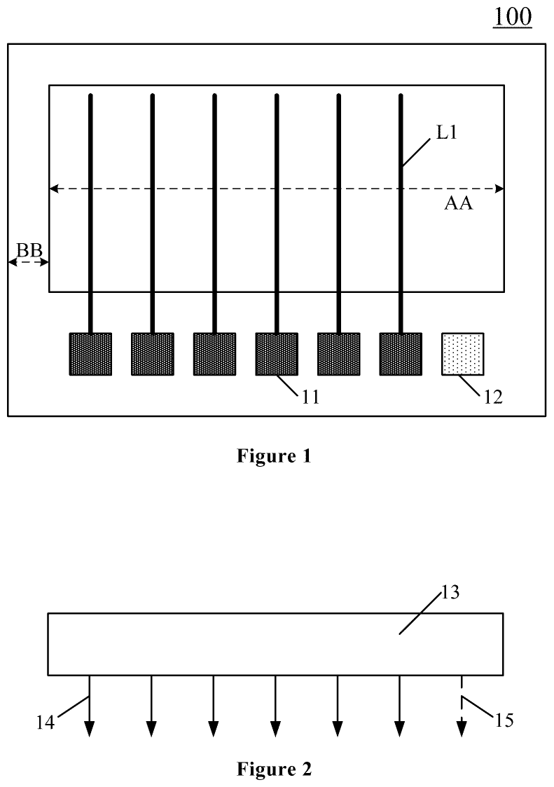

The present disclosure provides a display panel. FIG. 1 illustrates a schematic structural diagram of a display panel consistent with the disclosed embodiments of the present disclosure. Referring to FIG. 1, the display panel 100 includes a display area AA and a non-display area BB. The non-display area BB at least partially surrounds the display area AA. The display area AA includes a display driving signal line L1. The non-display area BB includes pads, and the pads include one or more first pad 11 and one or more second pad 12. The one or more first pad 11 is a test pad connected to the display driving signal line L1.

The one or more second pad 12 is not connected to the display driving signal line L1. One or more of the one or more second pad 12 is input with a first voltage signal and outputs a feedback signal.

Specifically, in one embodiment, as an example, the non-display area BB totally surrounds the display area AA. The display driving signal line L1 includes but is not limited to a data signal line that provides a data signal to a pixel. The display driving signal line L1 extends from the display area AA to the non-display area BB where the first pad 11 is disposed, and is connected with the first pad 11. In this case, the first pad 11 is a test pad configured for a light-up test of the display panel 100. The second pad 12 is not connected to the display driving signal line L1. In this case, the second pad 12 is a pad configured to detect whether there is misalignment between the probe on the test fixture and the pad on the display panel 100.

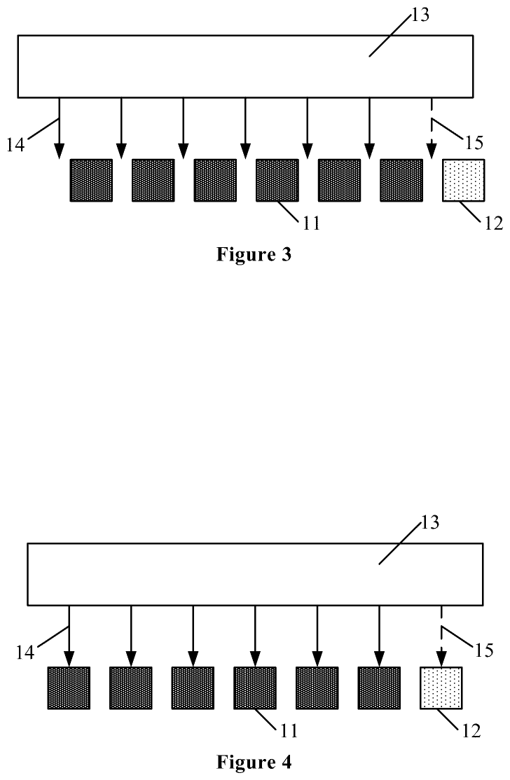

The present disclosure also provides a display-panel testing system. FIG. 2 illustrates a schematic structural diagram of a test fixture consistent with the disclosed embodiments of the present disclosure. FIG. 3 illustrates a schematic diagram of an alignment relationship between a probe on a test fixture and a pad on a display panel, consistent with the disclosed embodiments of the present disclosure. FIG. 4 illustrates a schematic diagram of another alignment relationship between a probe on a test fixture and a pad on a display panel, consistent with the disclosed embodiments of the present disclosure. Referring to FIGS. 2-4, the display-panel testing system includes a display panel 100 provided by the present disclosure, and a testing fixture 13.

As shown in FIGS. 2 and 3, the test fixture 13 includes one or more first probe 14, and one or more second probe 15. The one or more first probe 14 is configured to be electrically connected to the first pad 11 in the display panel 100. The one or more second probe 15 is configured to be electrically connected to the second pad 12 in the display panel 100.

The relative position relationship between the first pad 11 and the second pad 12 is fixed after the display panel is fabricated. The relative position relationship between the probes on the test fixture 13 is determined based on the positions of the pads on the display panel 100, or the relative position relationship of the pads on the display panel 100 is determined based on the position of the probes on the test fixture 13. As shown in FIG. 3, when the second probe 15 at the second pad 12 is misaligned with the second pad 12, it may indicate that the first probe 14 at the first pad 11 is also misaligned with the first pad 11. On the contrary, as shown in FIG. 4, when there is no misalignment between the second probe 15 at the second pad 12 and the second pad 12, it may indicate that there is no misalignment between the first probe 14 at the first pad 11 and the first pad 11.

In other words, the arrangement of the probes on the test fixture 13 is same as the arrangement of the pads on the display panel 100. When the second pad 12 and the second probe 15 are aligned normally, it may be determined that the first pad 11 and the first probe 14 are aligned normally. When the second pad 12 and the second probe 15 are abnormally aligned, it may be determined that the first pad 11 and the first probe 14 are abnormally aligned, that is, there is a misalignment problem between the probe on the test fixture 13 and the pad on the display panel 100.

It should be noted that, in one embodiment, the second pad 12 may be a new pad added based on an existing display panel. When the first pads 11 are not totally used, the unused first pad 11 may be used as the second pad 12. In this case, the unused first pad 11 is not connected to the display driving signal line L1.

Similarly, in the embodiment, the second probe 15 may be a new probe added based on an existing test fixture 13. When the first probes 14 are not totally used, the unused first probe 14 may be used as the second probe 15.

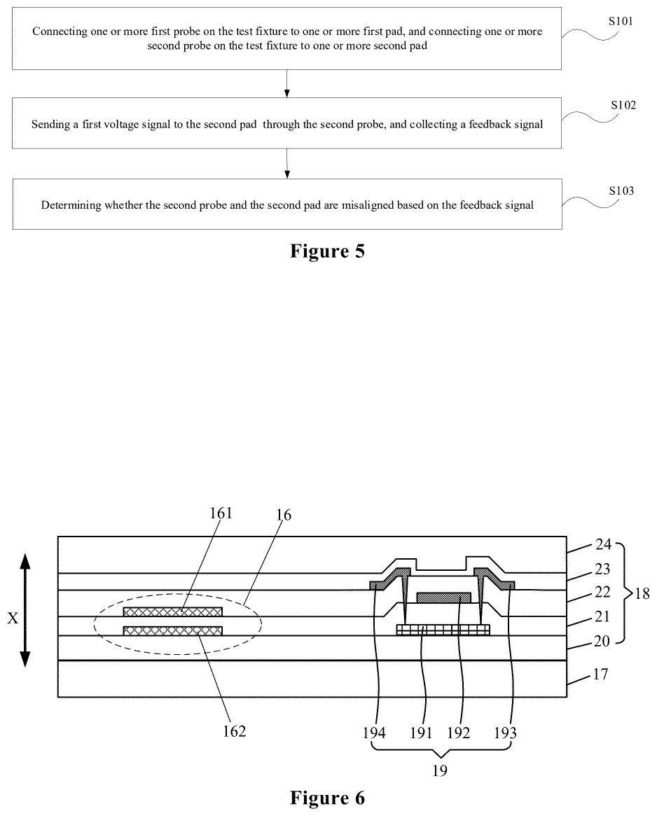

The present disclosure also provides a display-panel testing method. FIG. 5 illustrates a schematic flow chart of a display-panel testing method consistent with the disclosed embodiments of the present disclosure. Based on the display-panel testing system provided by the present disclosure, the display-panel testing method provided includes a first test stage. As shown in FIG. 5, in the first test stage, the display-panel testing method includes S101, S102 and S103.
S101: connecting one or more first probe 14 on the test fixture 13 to one or more first pad 11, and connecting one or more second probe 15 on the test fixture 13 to one or more second pad 12.
S102: sending a first voltage signal to the second pad 12 through the second probe 15, and collecting a feedback signal.
S103: determining whether the second probe 15 and the second pad 12 are misaligned based on the feedback signal.

It may be learnt from the above description that, at least before the light-up test of the display panel 100, the first voltage signal is sent to the second pad 12 using the second probe 15 connected to the second pad 12. Based on the feedback signal, the alignment relationship between the second probe 15 and the second pad 12 may be determined, and then the alignment relationship between the first probe 14 and the first pad 11 may be obtained. Accordingly, the purpose of determining whether there is misalignment between the probe on the test fixture 13 and the pad on the display panel 100 before the light-up test is performed, may be achieved.

In addition, since the second pad 12 is not connected to the display driving signal line L1, the first voltage signal may not be transmitted to the display driving signal line L1 during the alignment test process for the pad and the probe. In addition, during the light-up test process of the display panel 100, the second pad 12 may not provide the display driving signal to the display driving signal line L1. Accordingly, in the present disclosure, the procedure of determining whether there is misalignment between the probe on the test fixture 13 and the pad on the display panel 100, may not affect the normal light-up test of the display panel 100.

As such, in the technical solution of the present disclosure, by designing a second pad 12 for determining whether there is misalignment between the probe on the test fixture 13 and the pad on the display panel 100, and sending a first voltage signal to the second pad 12 using the second probe 15, it may be determined whether there is misalignment between the probe and the pad. When the probe and the pad are misaligned, the operator may be prompted to re-align in time, and detection errors caused by misalignment between the probe and the pad may be avoided. Accordingly, hidden dangers such as display panel burn-in and residual charge may be avoided, detection accuracy may be improved, and production yield of the display panel may be increased.

The method of notifying the operator when the probe and the pad are misaligned includes but is not limited to sound and light alarms.

FIG. 6 illustrates a schematic structural diagram of another display panel consistent with the disclosed embodiments of the present disclosure. In one embodiment, referring to FIG. 6, the display panel 100 also includes a capacitor structure 16. The capacitor structure 16 includes a first electrode plate 161 and a second electrode plate 162.

One or more second pad 12 is connected to one electrode plate of the first electrode plate 161 and the second electrode plate 162, and the other electrode plate is electrically connected to a fixed signal terminal.

Specifically, in one embodiment, the display panel 100 includes a substrate 17 and an array layer 18 disposed on one side of the substrate 17. The array layer 18 is disposed with a thin film transistor 19. The thin film transistor 19 is configured to form a circuit for the operation of the display panel 100, for example, to form a pixel circuit for the display panel 100 to control pixels. The present disclosure includes but is not limited to integrating the capacitor structure 16 on the array layer 18 through a semiconductor process.

As shown in FIG. 6, the thin film transistor 19 includes an active layer 191, a gate 192, a source 193, and a drain 194. The array layer 18 includes a buffer layer 20, a gate insulating layer 21 disposed between the active layer 191 and the gate 192, an interlayer insulating layer 22 disposed between the gate 192 and the source 193 and the drain 194, a passivation layer 23 disposed on a side of the source 193 and the drain 194 facing away from the interlayer insulating layer 22, and a planarization layer 24 disposed on a side of the passivation layer 23 facing away from the interlayer insulating layer 22. It should be noted that, in the present disclosure, as an example for description, the source 193 and the drain 194 are disposed on a same layer.

Optionally, the substrate 17 includes but is not limited to a substrate made of a flexible insulating material. The substrate has properties such as being stretchable, foldable or bendable. The material includes but is not limited to polyimide material (PI for short), polycarbonate material (PC for short), polyethylene terephthalate material (PET for short), or a combination thereof.

Optionally, the buffer layer 20 includes but is not limited to an inorganic material layer or an organic material layer. The material of the inorganic material layer includes but is not limited to silicon oxide, silicon nitride, silicon oxynitride, aluminum oxide, aluminum nitride, or a combination thereof. The material of the organic material layer includes but is not limited to acrylic, PI, or a combination thereof.

In one embodiment, as shown in FIG. 6, the first electrode plate 161 and the second electrode plate 162 are disposed opposite to each other in a first direction X. The first direction X is perpendicular to the plane where the display panel 100 is located. The first electrode plate 161 and the second electrode plate 162 are located on different metal layers.

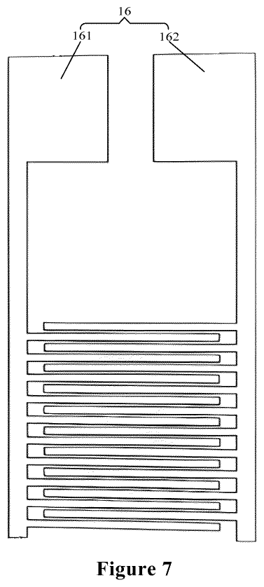

FIG. 7 illustrates a schematic diagram of a capacitor structure consistent with the disclosed embodiments of the present disclosure. In another embodiment, referring to FIG. 7, the capacitor structure 16 is an interdigital capacitor. The first electrode plate 161 and the second electrode plate 162 are disposed on a same metal layer.

It should be noted that the structure of the array layer 18 described above is exemplary. Taking the capacitor structure shown in FIG. 6 as an example, when the display panel 100 is designed as 10 masks, the first electrode plate 161 and the second electrode plate 162 may be made in the first metal layer M1 and the second metal layer M2 respectively. When the display panel 100 is designed as 11 masks, the first electrode plate 161 and the second electrode plate 162 may be arbitrarily selected to be made in the first metal layer M1, the second metal layer M2 or the third metal layer M3 according to the design conditions of the display panel 100.

Exemplarily, the first electrode plate 161 may be made in the first metal layer M1, and the second electrode plate 162 may be made in the second metal layer M2. Alternatively, the first electrode plate 161 may be made in the first metal layer M1, and the second electrode plate 162 may be made in the third metal layer M3. Alternatively, the first electrode plate 161 may be made in the second metal layer M2, and the second electrode plate 162 may be made in the third metal layer M3.

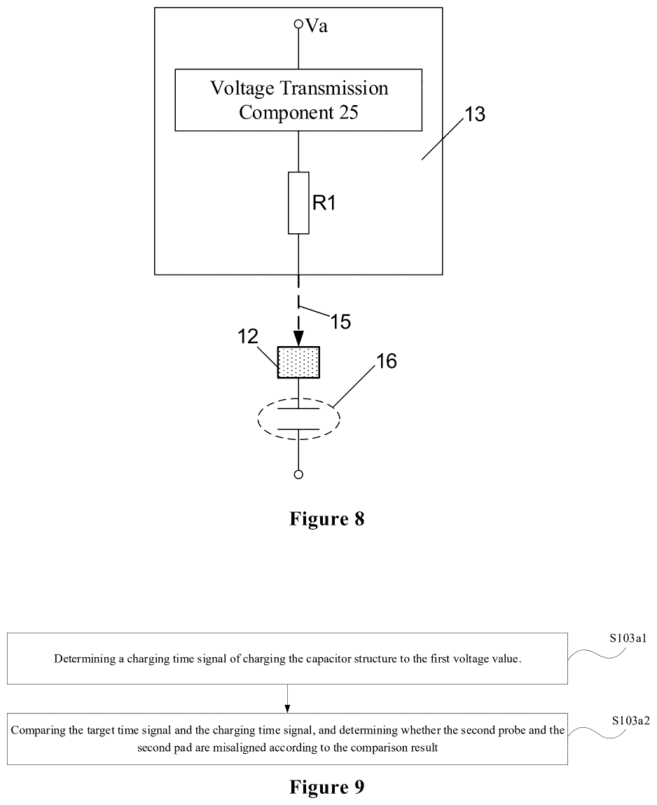

FIG. 8 illustrates a schematic structural diagram of an equivalent circuit of a display-panel testing system, consistent with the disclosed embodiments of the present disclosure. Referring to FIG. 8, after the capacitor structure 16 is integrated on the array layer 18, one of the plates in the capacitor structure 16 may be connected to the second pad 12, and the other plate may be electrically connected to a fixed signal terminal Vb. The fixed signal terminal Vb may be any level signal terminal such as GND, VGH, VGL, or VCOM in the display panel 100. The selection of voltage level is related to the GIP circuit wiring design in the display panel.

As shown in FIG. 8, the test fixture 13 includes a voltage transmission component 25 and a first resistor R1. The input terminal of the voltage transmission component 25 is electrically connected to the first voltage terminal Va, and the output terminal of the voltage transmission component 25 is electrically connected to the second probe 15 through a first resistor R1. The first voltage terminal Va is configured to provide a first voltage signal V1, and the voltage value represented by the first voltage signal V1 is the first voltage value. The feedback signal is a target time signal for the voltage value at the second probe 15 to rise to the first voltage value. The feedback signal may be collected by the test fixture 13, and the present disclosure does not limit a specific approach for collecting the feedback signal.

FIG. 9 illustrates a schematic flow chart of another display-panel testing method consistent with the disclosed embodiments of the present disclosure. Referring to FIG. 9, a possible implementation of S103: “determining whether the second probe 15 and the second pad 12 are misaligned based on the feedback signal”, includes S103a1 and S103a2.
S103a1: determining a charging time signal of charging the capacitor structure 16 to the first voltage value.
S103a2: comparing the target time signal and the charging time signal, and determining whether the second probe 15 and the second pad 12 are misaligned according to the comparison result.

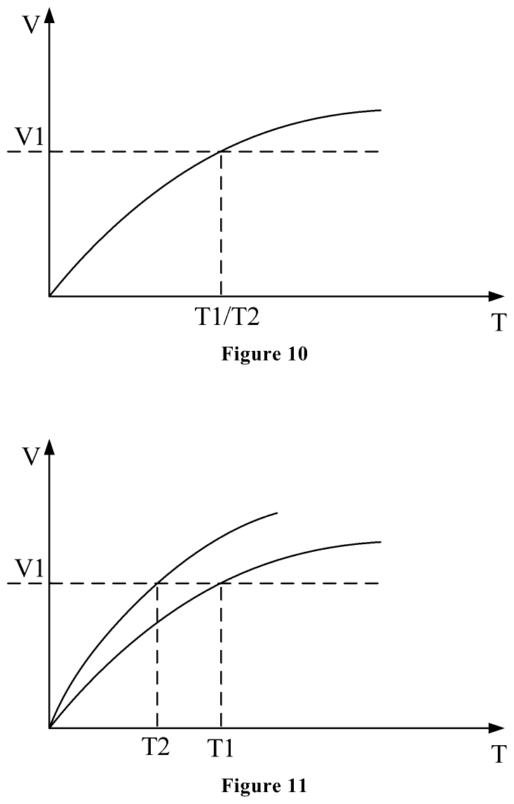

FIG. 10 illustrates a schematic curve of voltage and time, consistent with the disclosed embodiments of the present disclosure. FIG. 11 illustrates another schematic curve of voltage and time, consistent with the disclosed embodiments of the present disclosure. In FIGS. 10 and 11, the charging time signal for the capacitor structure 16 to be charged to the first voltage value is T1, and the target time signal for the voltage value at the second probe 15 to rise to the first voltage value is T2.

In the alignment detection stage of the probe and the pad, that is, the first test stage, the test fixture 13 may apply the first voltage signal V1 to the second probe 15 through the voltage transmission component 25 in the test fixture 13. In this case, the test fixture 13 may not apply any signal to the first probe 14.

When the second probe 15 and the second pad 12 are not misaligned, since the second pad 12 is connected to one of the plates in the capacitor structure 16, the second probe 15 is connected to the corresponding plate in the capacitor structure 16 through the second pad 12. In this case, the circuit path of the second probe 15, the second pad 12 and the capacitor structure 16 are in a connected state. Due to the existence of the capacitor structure 16, the target time signal T2 for the voltage value at the second probe 15 to rise to the first voltage value may be equal to the charging time signal T1 for the capacitor structure 16 to be charged to the first voltage value, as shown in FIG. 10.

In other words, in the first test stage, when the target time signal T2 for the voltage value at the second probe 15 to rise to the first voltage value is equal to the charging time signal T1 for the capacitor structure 16 to be charged to the first voltage value, this indicates that there is no misalignment between the second probe 15 and the second pad 12, and further indicates that there is no misalignment between the first probe 14 and the first pad 11.

When the second probe 15 is misaligned with the second pad 12, that is, the second probe 15 is not connected to the second pad 12, the second probe 15 is not connected to the electrode plate of the capacitor structure 16. In this case, the circuit path of the second probe 15, the second pad 12 and the capacitor structure 16 is disconnected at the connection point between the second probe 15 and the second pad 12. The first voltage signal V1 may only be transmitted to the second probe 15 and may not be further transmitted to the second pad 12 and the capacitor structure 16. The target time signal T2 for the voltage value at the second probe 15 to rise to the first voltage value may be less than the charging time signal T1 for the capacitor structure 16 to be charged to the first voltage value. That is, the voltage value at the second probe 15 may rise to the first voltage value in a shorter time, as shown in FIG. 11.

In other words, when the target time signal T2 for the voltage value at the second probe 15 to rise to the first voltage value is less than the charging time signal T1 for the capacitor structure 16 to be charged to the first voltage value, the second probe 15 may be misaligned with the second pad 12, and the first probe 14 may be misaligned with the first pad 11.

As such, in the technical solution of the present disclosure, the second pad 12 may be designed based on an existing display panel design. The array layer 18 includes but is not limited to a capacitor structure 16 integrated by a semiconductor process. By comparing the target time signal T2 for the voltage value at the second probe 15 to rise to the first voltage value and the charging time signal T1 for the capacitor structure 16 to be charged to the first voltage value, it may be determined whether the second probe 15 and the second pad 12 are misaligned, and whether the first probe 14 and the first pad 11 are misaligned.

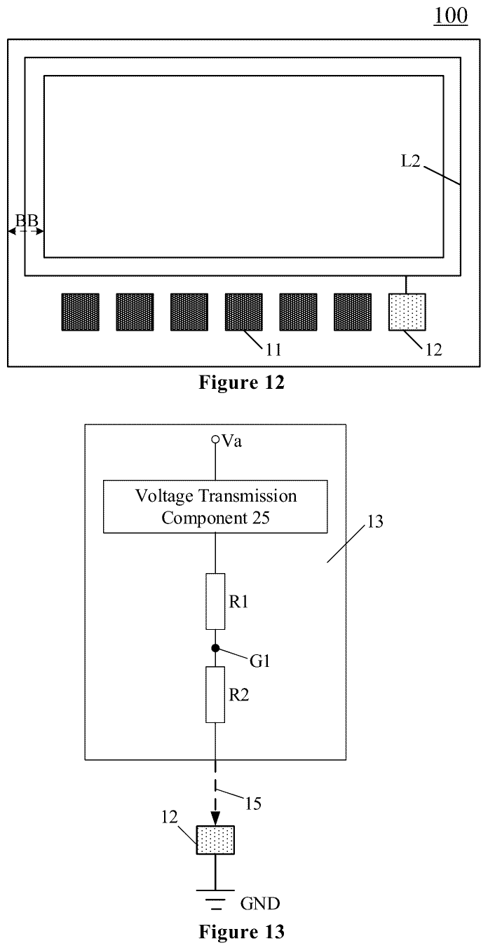

FIG. 12 illustrates a schematic structural diagram of another display panel consistent with the disclosed embodiments of the present disclosure. Referring to FIG. 12, in one embodiment, the display panel 100 also includes a ground trace L2. One or more second pad 12 is connected to the ground trace L2 through a connection line.

Specifically, in one embodiment, the ground trace L2 includes but is not limited to a ground loop disposed in the display panel 100. The ground loop is usually disposed around the display area AA. By connecting one or more second pad 12 to the ground trace L2 through a connection line, the grounding method of the second pad 12 may be simplified without complicated wiring.

FIG. 13 illustrates a schematic structural diagram of an equivalent circuit of another display-panel testing system, consistent with the disclosed embodiments of the present disclosure. Referring to FIG. 13, in one embodiment, the capacitor structure 16 is not integrated in the array layer 18. The second pad 12 is directly connected to the ground trace L2, that is, the second pad 12 is directly grounded.

As shown in FIG. 13, the test fixture 13 may include a voltage transmission component 25, a first resistor R1, and a second resistor R2. The input terminal of the voltage transmission component 25 is electrically connected to the first voltage terminal Va. The output terminal of the voltage transmission component 25 is electrically connected to the second probe 15 through the first resistor R1 and the second resistor R2 in sequence. The connection node between the first resistor R1 and the second resistor R2 is the first connection node G1. The first voltage terminal Va may provide the first voltage signal V1, and the feedback signal is the voltage signal at the first connection node G1.

It should be noted that the feedback signal may be collected by the test fixture 13, or other methods.

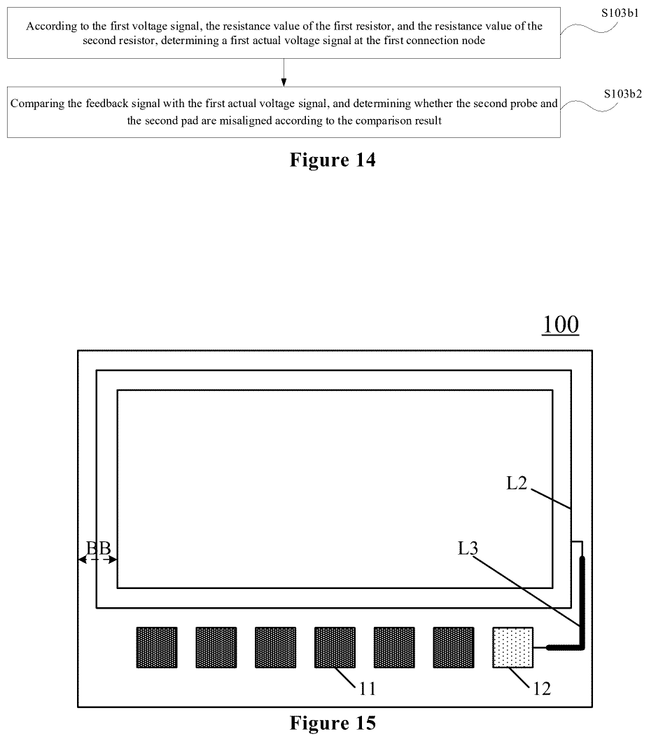

FIG. 14 illustrates a schematic flow chart of another display-panel testing method consistent with the disclosed embodiments of the present disclosure. Referring to FIG. 14, a possible implementation of S103: “determining whether the second probe 15 and the second pad 12 are misaligned based on the feedback signal”, includes S103b1 and S103b2.
S103b1: according to the first voltage signal V1, the resistance value of the first resistor R1, and the resistance value of the second resistor R2, determining a first actual voltage signal at the first connection node G1.
S103b2: comparing the feedback signal with the first actual voltage signal, and determining whether the second probe 15 and the second pad 12 are misaligned according to the comparison result.

Specifically, in one embodiment, the first actual voltage signal at the first connection node G1 may be determined to be V2 according to the first voltage signal V1, the resistance value of the first resistor R1, and the resistance value of the second resistor R2. That is, when there is no misalignment between the second probe 15 and the second pad 12, the first actual voltage signal at the first connection node G1 is V2, where V2=V1×R2/(R1+R2).

In the alignment detection stage of the probe and the pad, that is, the first test stage, the test fixture 13 may apply the first voltage signal V1 to the second probe 15 through the voltage transmission component 25 in the test fixture 13. In this case, the test fixture 13 may not apply any signal to the first probe 14.

When the second probe 15 and the second pad 12 are not misaligned, the circuit path of the first resistor R1, the second resistor R2, the second probe 15 and the second pad 12 is in a connected state. The voltage signal at the first connection node G1 represented by the detected feedback signal is equal to the first actual voltage signal V2.

In other words, in the first test stage, when the voltage signal at the first connection node G1 represented by the detected feedback signal is equal to the first actual voltage signal V2, there is no misalignment between the second probe 15 and the second pad 12, and there is no misalignment between the first probe 14 and the first pad 11.

When the second probe 15 is misaligned with the second pad 12, that is, the second probe 15 is not connected to the second pad 12, the circuit path of the first resistor R1, the second resistor R2, the second probe 15 and the second pad 12 is disconnected at the connection point between the second probe 15 and the second pad 12. The voltage signal at the first connection node G1 represented by the detected feedback signal is not equal to the first actual voltage signal V2.

In other words, in the first test stage, when the voltage signal at the first connection node G1 represented by the detected feedback signal is not equal to the first actual voltage signal V2, the second probe 15 is misaligned with the second pad 12, and the first probe 14 is misaligned with the first pad 11.

As such, in the technical solution of the present disclosure, the second pad 12 is designed based on an existing display panel design, and the second pad 12 is grounded. By comparing the voltage signal at the first connection node G1 with the first actual voltage signal V2, it may be determined whether the second probe 15 and the second pad 12 are misaligned, and it may thus be determined whether the first probe 14 and the first pad 11 are misaligned. Furthermore, the technical solution of the present disclosure may determine whether the pad and the probe are misaligned before the light-up test. Accordingly, the problem of panel burns caused by direct power-on during the light-up test of the panel, when the probe and the pad are misaligned, may be avoided.

It should be noted that, compared with the technical solution of setting the capacitor structure 16, the technical solution shown in FIG. 13 may require adaptive improvement of the internal circuit structure of the test fixture 13. The second resistor R2 may be connected in series between the first resistor R1 and the second probe 15 for detecting the voltage signal of the first connection node G1.

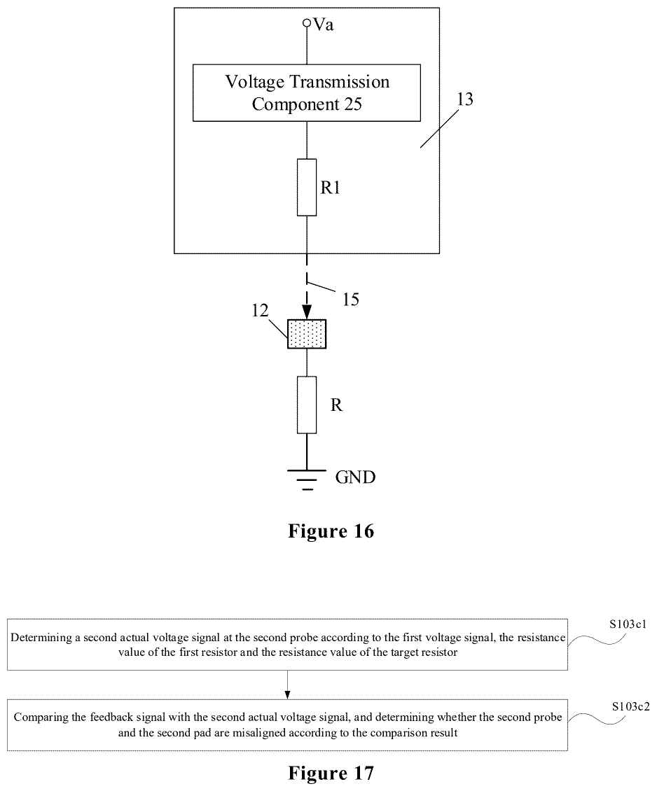

FIG. 15 illustrates a schematic structural diagram of another display panel consistent with the disclosed embodiments of the present disclosure. FIG. 16 illustrates a schematic structural diagram of an equivalent circuit of another display-panel testing system, consistent with the disclosed embodiments of the present disclosure. Referring to FIGS. 15 and 16, the display panel 100 also includes a ground trace L2 and a target resistor R. One or more second pad 12 is connected to the ground trace L2 through a connection line and a target resistor R.

In one embodiment, as shown in FIG. 15, the target resistor R is in a form of a metal trace L3. The metal trace L3 may be integrated in the array layer 18 through a semiconductor process, or may be formed in other approaches. When the display panel 100 is designed as 10 masks, the metal trace L3 may be disposed in the first metal layer M1 or the second metal layer M2. When the display panel 100 is designed as 11 masks, the metal trace may be disposed in the first metal layer M1 or the second metal layer M2 or the third metal layer M3.

Specifically, in one embodiment, the ground trace L2 includes but is not limited to the ground loop disposed in the display panel 100. The ground loop may be arranged around the display area AA. By connecting one or more second pad 12 to the ground trace L2 through the connection line and the target resistor R, the grounding method of the second pad 12 may be simplified without complicated wiring.

In one embodiment, as shown in FIG. 16, the capacitor structure 16 is not integrated in the array layer 18, and the second pad 12 is directly connected to the ground trace L2 through the target resistor R. That is, the second pad 12 is directly grounded through the target resistor R.

In one embodiment, as shown in FIG. 16, the test fixture 13 includes a voltage transmission component 25 and a first resistor R1. The input terminal of the voltage transmission component 25 is electrically connected to the first voltage terminal Va, and the output terminal of the voltage transmission component 25 is electrically connected to the second probe 15 through the first resistor R1. The first voltage terminal Va is configured to provide the first voltage signal V1, and the feedback signal is a voltage signal at the second probe 15.

It should be noted that the feedback signal may be collected by the test fixture 13, and may be collected by other approaches.

FIG. 17 illustrates a schematic flow chart of another display-panel testing method consistent with the disclosed embodiments of the present disclosure. Referring to FIG. 17, a possible implementation of S103: “determining whether the second probe 15 and the second pad 12 are misaligned based on the feedback signal”, includes S103c1 and S103c2.
S103c1: determining a second actual voltage signal at the second probe 15 according to the first voltage signal V1, the resistance value of the first resistor R1 and the resistance value of the target resistor R.
S103c2: comparing the feedback signal with the second actual voltage signal, and determining whether the second probe 15 and the second pad 12 are misaligned according to the comparison result.

Specifically, in one embodiment, the second actual voltage signal at the second probe 15 may be determined to be V3 according to the first voltage signal V1, the resistance value of the first resistor R1, and the resistance value of the target resistor R. When there is no misalignment between the second probe 15 and the second pad 12, the second actual voltage signal at the second probe 15 is V3, where V3=V1×R/(R1+R).

In the alignment detection stage of the probe and the pad, that is, the first test stage, the test fixture 13 may apply the first voltage signal V1 to the second probe 15 through the voltage transmission component 25 in the test fixture 13. In this case, the test fixture 13 may not apply any signal to the first probe 14.

When the second probe 15 and the second pad 12 are not misaligned, the circuit path of the first resistor R1, the second probe 15, the second pad 12 and the target resistor R is in a connected state, and the voltage signal at the second probe 15 represented by the detected feedback signal is equal to the second actual voltage signal V3.

In other words, in the first test stage, when the voltage signal at the second probe 15 represented by the detected feedback signal is equal to the second actual voltage signal V3, the second probe 15 and the second pad 12 are not misaligned, and there is no misalignment between the first probe 14 and the first pad 11.

When the second probe 15 is misaligned with the second pad 12, that is, the second probe 15 is not connected to the second pad 12, the circuit path of the first resistor R1, the second probe 15, the second pad 12 and the target resistor R is disconnected at the connection point between the second probe 15 and the second pad 12. The voltage signal at the second probe 15 represented by the detected feedback signal is not equal to the second actual voltage signal V3.

In other words, in the first test stage, when the voltage signal at the second probe 15 represented by the detected feedback signal is not equal to the second actual voltage signal V3, the second probe 15 is misaligned with the second pad 12, and the first probe 14 is misaligned with the first pad 11.

As such, in the technical solution the present disclosure, the second pad 12 may be designed based on an existing display panel design, and the second pad 12 may be grounded through a target resistor R. By comparing the voltage signal at the second probe 15 with the second actual voltage signal V3, it may be determined whether the second probe 15 and the second pad 12 are misaligned, and it may be also determined whether the first probe 14 and the first pad 11 are misaligned.

It should be noted that, compared with the technical solution of setting the capacitor structure 16, the technical solution shown in FIG. 17 does not require improvement on the internal circuit structure of the test fixture 13. The test fixture 13 with a same structure may be used to detect display panels 100 with different structures.

In one embodiment, when the quantity of the one or more second pad 12 is one, the second pad 12 may be disposed at any position of the non-display area BB. Specifically, in one embodiment, when the quantity of the one or more second pad 12 is one, the second pad 12 may be disposed at any position of the non-display area BB according to the shape of the display panel 100. The present disclosure does not specifically limit a specific position of the second pad 12.

In one embodiment, when the quantity of the one or more second pad 12 is more than one, two or more second pads 12 may be arranged in a same row, or two or more second pads 12 may be arranged in different rows.

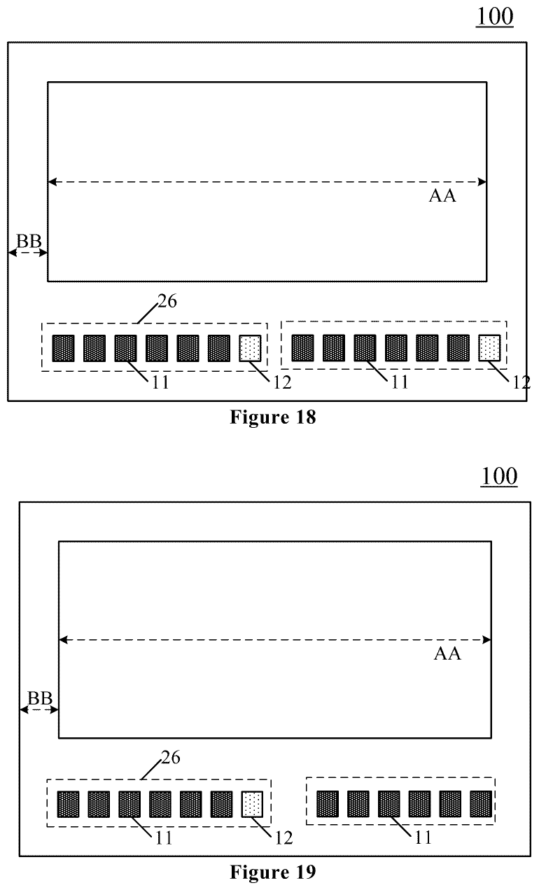

FIG. 18 illustrates a schematic structural diagram of another display panel consistent with the disclosed embodiments of the present disclosure. FIG. 19 illustrates a schematic structural diagram of another display panel consistent with the disclosed embodiments of the present disclosure. Specifically, referring to FIGS. 18 and 19, a plurality of the first pads 11 may form one or more test pad group 26, and one or more of the test pad group 26 is correspondingly provided with a second pad 12. As shown in FIG. 18, the plurality of the first pads 11 forms two test pad groups 26, and each of the two test pad groups 26 is provided with a corresponding second pad 12. As shown in FIG. 19, the plurality of first pads 11 forms two test pad groups 26. One of the two test pad groups 26 has a corresponding second pad 12, and the other of the two test pad groups 26 does not have a corresponding second pad 12.

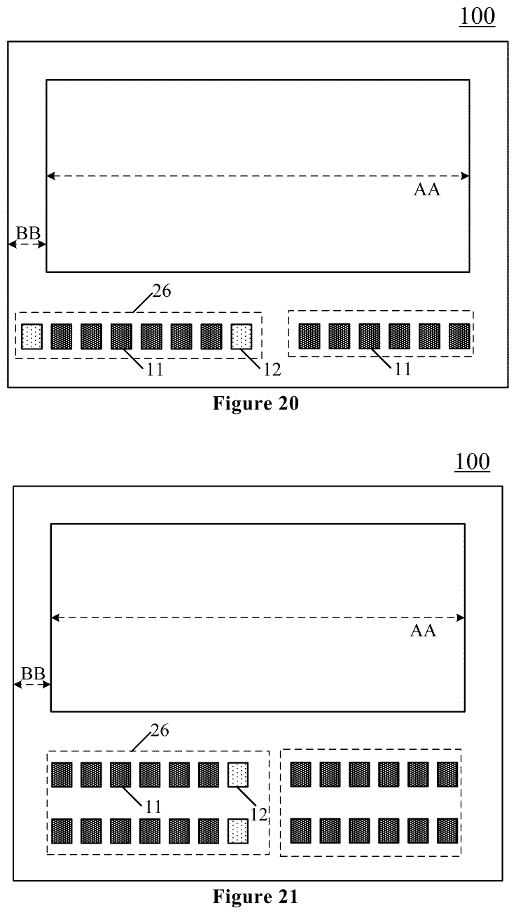

FIG. 20 illustrates a schematic structural diagram of another display panel consistent with the disclosed embodiments of the present disclosure. Referring to FIG. 20, a plurality of first pads 11 in a same test pad group 26 is arranged in sequence in a row direction. One or more test pad group 26 is provided with two second pads 12 correspondingly. The two second pads 12 in a same test pad group 26 are respectively disposed at two ends of the plurality of first pads 11.

Considering that the probes of the test fixture 13 is an integral structure, when the probes and pads are misaligned, when there is no rotational offset between the probes on the test fixture and the pads on the display panel, the offset of the probe misalignment at the edge and the middle of each test pad group 26 may be same. When there is a rotational offset, the offset of the probe misalignment at the edge of each test pad group 26 may be the largest. As such, when there is no misalignment between the pads and the probes at the two end positions of each test pad group 26, it may be determined that the alignment between the pads in the middle and the probes is normal. Accordingly, in one embodiment, when two second pads 12 are arranged at the two end positions of each test pad group 26, accuracy of the detection of the misalignment between the pad and the probe may be improved.

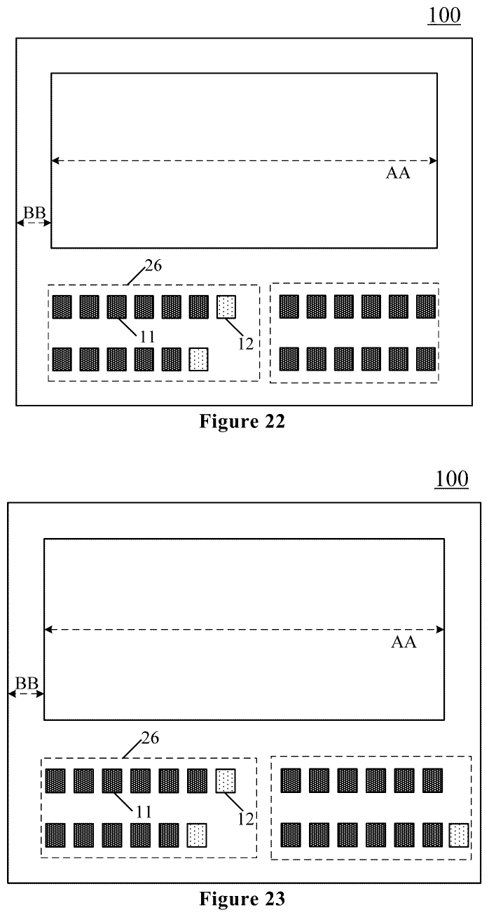

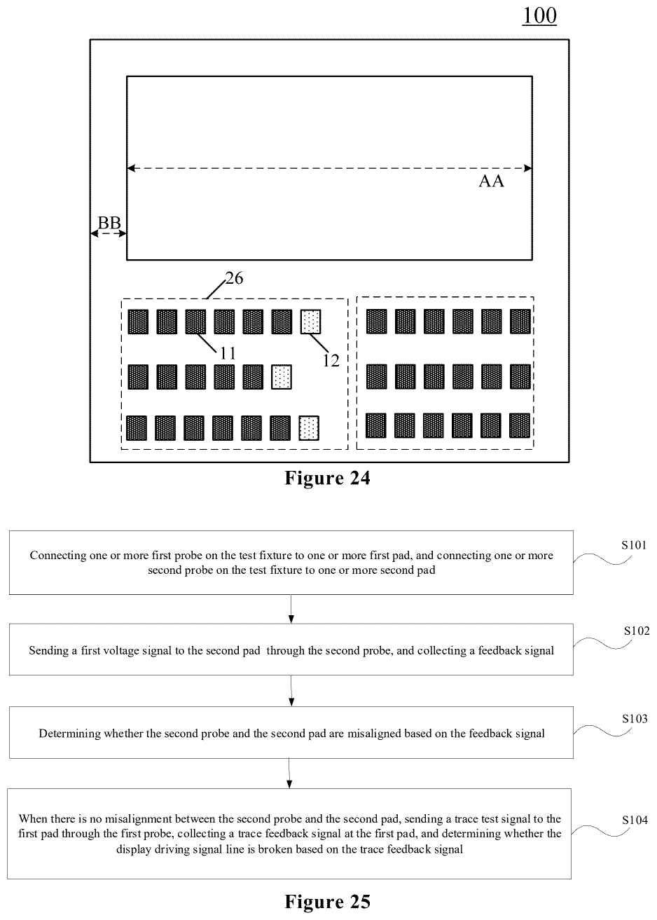

In some other embodiments, the second pads 12 may also be disposed at other positions of each test pad group 26 according to actual needs. FIG. 21 illustrates a schematic structural diagram of another display panel consistent with the disclosed embodiments of the present disclosure. FIG. 22 illustrates a schematic structural diagram of another display panel consistent with the disclosed embodiments of the present disclosure. FIG. 23 illustrates a schematic structural diagram of another display panel consistent with the disclosed embodiments of the present disclosure. Referring to FIGS. 21-23, the plurality of first pads 11 in a same test pad group 26 may be arranged in an array. In the array arrangement, two or more rows are respectively provided with one or more second pad 12. FIG. 24 illustrates a schematic structural diagram of another display panel consistent with the disclosed embodiments of the present disclosure. Referring to FIG. 24, a plurality of first pads 11 in a same test pad group 26 may be arranged in an array. In the arrangement array, three or more second pads 12 are disposed, and geometric centers of three second pads 12 of the three or more second pads 12 form three vertices of a virtual triangle.

As such, the selection of the position of the second pad 12 is for the purpose of achieving an accurate detection result of the misalignment between the pad and the probe.

FIG. 25 illustrates a schematic flow chart of another display-panel testing method consistent with the disclosed embodiments of the present disclosure. Referring to FIG. 25, the display-panel testing method also includes a second test stage. In the second test stage, the display-panel testing method also includes S104.
S104: when there is no misalignment between the second probe 15 and the second pad 12, sending a trace test signal to the first pad 11 through the first probe 14, collecting a trace feedback signal at the first pad 11, and determining whether the display driving signal line L1 is broken based on the trace feedback signal.

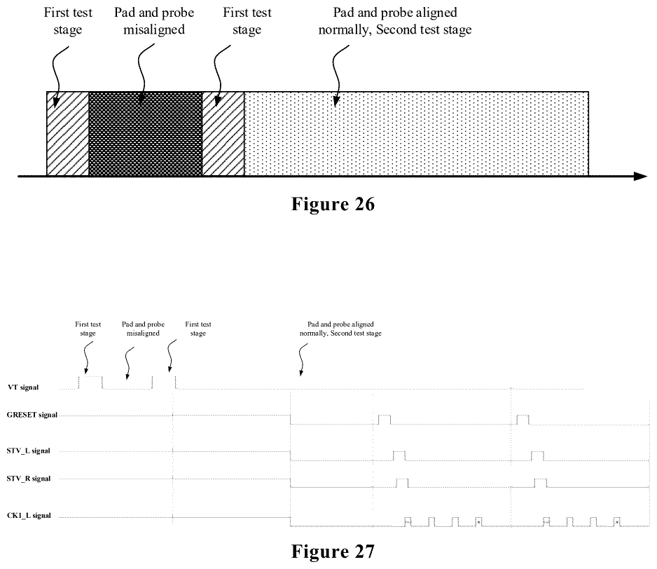

FIG. 26 illustrates a schematic diagram of test stage distribution corresponding to a display-panel testing method, consistent with the disclosed embodiments of the present disclosure. FIG. 27 illustrates a timing diagram corresponding to a display-panel testing method, consistent with the disclosed embodiments of the present disclosure. Specifically, referring to FIGS. 26 and 27, the display-panel testing method includes executing the first test stage one or more times and executing the second teste stage one time. The second test stage is executed after one or more first test stages have been completed, and the test result of the first test stage closest to the second test stage is that the second probe and the second pad are not misaligned.

As shown in FIGS. 26 and 27, the testing method is equivalent to a one-time testing method. That is, before using the test fixture 13 to test the display driving signal line L1, one or more alignment test between the pad and the probe is required. Only when there is no misalignment between the pad and the probe, the second test stage may be executed, that is, the test fixture 13 may be used to test the display driving signal line L1.

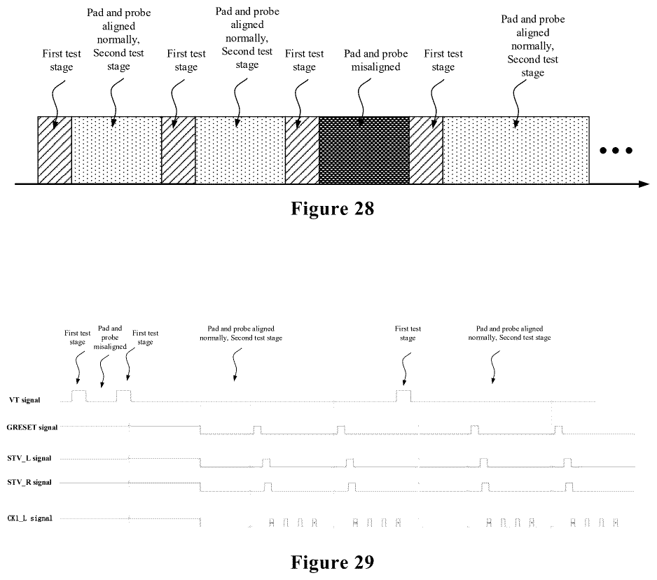

FIG. 28 illustrates a schematic diagram of test stage distribution corresponding to another display-panel testing method, consistent with the disclosed embodiments of the present disclosure. FIG. 29 illustrates a timing diagram corresponding to another display-panel testing method, consistent with the disclosed embodiments of the present disclosure. Referring to FIGS. 28 and 29, the display-panel testing method includes executing the first test stage one or more times and executing the second test stage one or more times. Between two adjacent second test stages, the first test stage may be executed one or more times.

As shown in FIGS. 28 and 29, the testing method is equivalent to a real-time testing method. Before the test fixture 13 may be used to test the display driving signal line L1, one or more times of alignment test between the pad and the probe needs to be executed. Only when there is no misalignment between the pad and the probe, the second test stage may be started, that is, the test fixture 13 may be used to test the display driving signal line L1. In addition, in the process of using the test fixture 13 to test the display driving signal line L1, the first test stage needs to be executed in an interleaved way. During the interleaved execution of the first test stage, testing the display driving signal line L1 with the test fixture 13 is stopped. In this way, the problem of misalignment between the probe and the pad may not occur during the process of using the test fixture 13 to test the display driving signal line L1. Accordingly, test errors caused by the misalignment between the probe and the pad may be avoided, and hidden dangers such as display panel burns and residual charge may be prevented, test accuracy may be improved, and production yield of display panels may be improved.

It should be noted that in FIGS. 27 and 29, the VT signal, the GRESET signal, the STV_L signal, the STV_R signal, and the CK1_L signal are part of the signals required for testing the display panel 100 based on the test fixture 13. Taking the VT signal as an example, when executing the first test stage, the VT signal is at a high level, that is, the test fixture 13 does not send a line test signal to the first pad 11 through the first probe 14 at this moment. The display panel 100 may be tested by the cooperation of various signals.

As disclosed, the technical solutions of the present disclosure have the following advantages.

The present application provides a display panel, a testing system for a display panel, and a testing method for a display panel. The first pad in the display panel is connected to the display driving signal line. The first pad is a test pad configured for a light-up test of the display panel. The second pad is not connected to the display driving signal line. The second pad is a pad configured to determine whether there is misalignment between the probe on the test fixture and the pad on the display panel.

The relative position relationship between the first pad and the second pad is fixed after the display panel is fabricated. The relative position relationship of the probes on the test fixture may be determined based on the positions of the pads on the display panel, or the relative position relationship of the pads on the display panel may be determined based on the positions of the probes on the test fixture. Accordingly, when the second probe at the second pad is misaligned with the second pad, it may indicate that the first probe 14 at the first pad is also misaligned with the first pad. On the contrary, when there is no misalignment between the second probe at the second pad and the second pad, it may indicate that there is no misalignment between the first probe at the first pad and the first pad.

In the above design, by inputting the first voltage signal to the second pad, based on the feedback signal, it may be determined whether there is misalignment between the probe on the test fixture and the pad on the display panel. In addition, since the second pad is not connected to the display driving signal line, the first voltage signal may not be transmitted to the display driving signal line. Accordingly, a process of determining whether there is misalignment between the probe on the test fixture and the pad on the display panel may not affect the light-up test of the display panel.

The embodiments disclosed herein are exemplary only and not limiting the scope of the present disclosure. Various combinations, alternations, modifications, equivalents, or improvements to the technical solutions of the disclosed embodiments may be obvious to those skilled in the art. Without departing from the spirit and scope of this disclosure, such combinations, alternations, modifications, equivalents, or improvements to the disclosed embodiments are encompassed within the scope of the present disclosure.

What is claimed is:

1. A display panel, comprising a display area and a non-display area, wherein:
the non-display area at least partially surrounds the display area;
the display area includes a display driving signal line;
the non-display area includes a plurality of pads, and the plurality of pads includes one or more first pad and one or more second pad;
one or more first pad of the one or more first pad is a test pad connected to the display driving signal line; and
one or more second pad of the one or more second pad is not connected to the display driving signal line, and one or more second pad of the one or more second pad is input with a first voltage signal and outputs a feedback signal.

2. The display panel according to claim 1, further comprising a capacitor structure, wherein:
the capacitor structure includes a first electrode plate and a second electrode plate; and
one or more second pad of the one or more second pad is connected to one electrode plate of the first electrode plate and the second electrode plate.

3. The display panel according to claim 2, wherein:
the capacitor structure is an interdigital capacitor; and
the first electrode plate and the second electrode plate are disposed on a same metal layer.

4. The display panel according to claim 2, wherein:
the first electrode plate and the second electrode plate are disposed opposite to each other in a first direction, wherein the first direction is perpendicular to a plane where the display panel is located; and
the first electrode plate and the second electrode plate are located on different metal layers.

5. The display panel according to claim 1, further comprising a ground trace, wherein:
one or more second pad of the one or more second pad is connected to the ground trace through a connection line.

6. The display panel according to claim 1, further comprising a ground trace and a target resistor, wherein:
one or more second pad of the one or more second pad is connected to the ground trace through a connection line and the target resistor.

7. The display panel according to claim 6, wherein:
the target resistor is a metal trace.

8. The display panel according to claim 1, wherein:
when a quantity of the one or more second pad is one, a location of the one or more second pad in the non-display area is not limited.

9. The display panel according to claim 1, wherein:
when a quantity of the one or more second pad is two or more, two or more second pads of the one or more second pad are arranged at a same row, or the two or more second pads are arranged at different rows.

10. A display-panel testing system, comprising a display panel and a testing fixture, wherein:
the display panel includes a display area and a non-display area, wherein the non-display area at least partially surrounds the display area, the display area includes a display driving signal line, the non-display area includes a plurality of pads, the plurality of pads includes one or more first pad and one or more second pad, one or more first pad of the one or more first pad is a test pad connected to the display driving signal line, one or more second pad of the one or more second pad is not connected to the display driving signal line, and one or more second pad of the one or more second pad is input with a first voltage signal and outputs a feedback signal; and
the test fixture includes one or more first probe and one or more second probe, wherein one or more first probe of the one or more first probe is electrically connected to the one or more the first pad in the display panel, and one or more second probe of the one or more second probe is electrically connected to the one or more second pad in the display panel.

11. The system according to claim 10, wherein:
the display panel further includes a capacitor structure, wherein the capacitor structure includes a first electrode plate and a second electrode plate, one or more second pad of the one or more second pad is connected to one electrode plate of the first electrode plate and the second electrode plate, and another electrode plate of the first electrode plate and the second electrode plate is electrically connected to a fixed signal terminal; and
the one or more second probe is connected to the one or more second pad.

12. The system according to claim 11, wherein:
the test fixture includes a voltage transmission component and a first resistor;
an input terminal of the voltage transmission component is electrically connected to a first voltage terminal, and an output terminal of the voltage transmission component is electrically connected to the one or more second probe through the first resistor; and
the first voltage terminal is configured to provide the first voltage signal, a voltage value represented by the first voltage signal is a first voltage value, and the feedback signal is a target time signal for a voltage value at the one or more second probe to rise to the first voltage value.

13. The system according to claim 10, wherein:
the display panel further includes a ground trace, and one or more second pad of the one or more second pad is connected to the ground trace through a connection line; and
the one or more second probe is connected to the one or more second pad.

14. The system according to claim 13, wherein:
the test fixture includes a voltage transmission component, a first resistor, and a second resistor;
an input terminal of the voltage transmission component is electrically connected to a first voltage terminal, an output terminal of the voltage transmission component is electrically connected to the one or more second probe through the first resistor and the second resistor in sequence, and a connection node between the first resistor and the second resistor is a first connection node; and
the first voltage terminal is configured to provide the first voltage signal, and the feedback signal is a voltage signal at the first connection node.

15. The system according to claim 10, wherein:
the display panel further includes a ground trace and a target resistor;
one or more second pad of the one or more second pad is connected to the ground trace through a connection line and the target resistor; and
the one or more second probe is connected to the one or more second pad.

16. The system according to claim 15, wherein:
the test fixture includes a voltage transmission component and a first resistor;
an input terminal of the voltage transmission component is electrically connected to a first voltage terminal, and an output terminal of the voltage transmission component is electrically connected to the one or more probe through the first resistor; and
the first voltage terminal is configured to provide the first voltage signal, and the feedback signal is a voltage signal at the one or more second probe.

17. A display-panel testing method, applicable to a display-panel testing system, wherein:
the display-panel testing system includes a display panel and a testing fixture, wherein the display panel includes a display area and a non-display area, wherein the non-display area at least partially surrounds the display area, the display area includes a display driving signal line, the non-display area includes a plurality of pads, the plurality of pads includes one or more first pad and one or more second pad, one or more first pad of the one or more first pad is a test pad connected to the display driving signal line, one or more second pad of the one or more second pad is not connected to the display driving signal line, and one or more second pad of the one or more second pad is input with a first voltage signal and outputs a feedback signal; and the test fixture includes one or more first probe and one or more second probe, wherein one or more first probe of the one or more first probe is electrically connected to the one or more the first pad in the display panel, and one or more second probe of the one or more second probe is electrically connected to the one or more second pad in the display panel; and
the display-panel testing method includes a first test stage, and in the first test stage, the display-panel testing method includes:
connecting one or more first probe of the one or more first probe on the test fixture to one or more first pad of the one or more first pad, and connecting one or more second probe of the one or more second probe on the test fixture to one or more second pad of the one or more second pad;
sending the first voltage signal to the one or more second pad through the one or more second probe, and collecting the feedback signal; and
determining whether the one or more second probe and the one or more second pad are misaligned based on the feedback signal.

18. The method according to claim 17, wherein:
when there is no misalignment between the one or more second probe and the one or more second pad, the method further includes a second test stage, wherein in the second test stage, the method includes:
sending a trace test signal to the one or more first pad through the one or more first probe;
collecting a trace feedback signal at the one or more first pad; and
determining whether the display driving signal line is broken based on the trace feedback signal.

19. The method according to claim 18, comprising:
executing the first test stage one or more times and executing the second teste stage one time, wherein the second test stage is executed after the executing the first test stage one or more times is completed, and a test result of the first test stage closest to the second test stage is that the one or more second probe and the one or more second pad are not misaligned.

20. The method according to claim 18, comprising:
executing the first test stage one or more times and executing the second test stage one or more times, wherein between two adjacent second test stages of the second test stage, the first test stage is executed one or more times.
